(19) United States
(12) Patent Application Publication
(10) Pub. No.: US 2012/0080088 A1
(43) Pub. Date: Apr. 5, 2012

(54) Method of Contacting a Semiconductor Substrate

(75) Inventors: Peter Grabitz, Zentern (DE); Juergen Koehler, Waiblingen (DE); Tobias Roeder, Stuttgart (DE); Juergen H. Werner, Stuttgart (DE)

(73) Assignee: Universitaet Stuttgart, Stuttgart (DE)

(21) Appl. No.: 13/283,947

(22) Filed: Oct. 28, 2011

Related U.S. Application Data
(63) Continuation of application No. PCT/EP2010/002364, filed on Apr. 17, 2010.

(30) Foreign Application Priority Data
May 5, 2009 (DE) 10 2009 020 774

(51) Int. Cl. H01L 31/02; H01L 31/18

(52) U.S. Cl. 136/256; 438/72; 438/98; 257/E31.127; 257/E31.124

(57) ABSTRACT

A method is disclosed for making contact with a semiconductor substrate, in particular for making contact with solar cells, in which a metallic seed structure is generated on the surface through a dielectric or passivating layer by means of an LIFT process, and the seed structure is then reinforced.

### CROSS REFERENCES TO RELATED APPLICATIONS

This application is a continuation of International Patent Application PCT/EP2010/002364, filed on Apr. 17, 2010 designating the U.S., which International Patent Application has been published in German language and claims priority from German patent application 102009020774.0, filed on May 5, 2009. The entire contents of these applications is incorporated herein by reference.

### BACKGROUND OF THE INVENTION

The invention relates to a method for contacting a semiconductor substrate, in particular for contacting solar cells.

On a small scale, contact can be made particularly well with solar cells by vapour deposition of lithographically prestructured samples. However, this method is too expensive for large-scale production, since a large number of process steps are required, and the majority of the metal used is lost by vapour deposition of the entire sample.

For this reason, the screen-printing process is widely used in industry for making contact with solar cells. The disadvantages of this method are that a high-temperature step is required in order to make contact with the solar cell. In addition, the contact resistance of screen-printing lines is approximately 10⁻³ to 10⁻² Ohm cm² greater than in the case of vapour-deposited contacts. The glass diffuser frits and the porosity of the lines reduce the line conductivity by a factor of approximately 4 in comparison to lines consisting of pure metal. A further disadvantage is the aspect ratio of screen-printing lines, which limits the minimum line width to approximately 100 μm, with a line height of approximately 20 μm.

A series of alternative contact-making methods have therefore been proposed for solar cells, although they all have certain disadvantages.

DE 199 15 666 A1 discloses a method for making selective contact with solar cells, in which a surface with which contact is to be made is coated with a dielectric passivation layer, and this passivation layer is removed by means of laser ablation, that is to say by the direct influence of laser light in the course of the ablation, until the bare surface located underneath is exposed. After the local exposure of the surface with which contact is to be made, selective contact is made by application of metal over the entire surface of the rear face, or a lift-off technique followed by electrochemical reinforcement for the front face. However, in this method, the contact must in general be subsequently treated at temperatures above 300° C. in order to achieve good resistance values, which means an additional process step, which furthermore restricts the choice of the passivation layers.

DE 100 46 170 A1 discloses a further method for making contact with solar cells, in which a metal layer is applied to the passivating, dielectric layer of a solar cell and briefly locally heated at a point or linearly by means of a radiation source, as a result of which a fusion mixture is formed from the metal layer, the dielectric layer and the semiconductor, which is intended to produce a good electrical contact between the semiconductor and the metal layer, after solidification.

Nevertheless, the contact resistances of the layer produced in this way are not satisfactory in every case.

DE 10 2006 030 822 A1 discloses a further method for making contact with solar cells, in which a metallic contact structure is applied to the surface of a solar cell by means of an ink containing metal, using the ink-jet process. A temperature step is then carried out at approximately 400° C., in order to form the contact between the applied metal paste and the semiconductor. After completion of this method step, the contact lines produced in this way are electrochemically reinforced in an electrolytic bath.

Ink-jet processes such as these have the fundamental disadvantage that the choice of the contact materials is greatly restricted, since they must be provided as ink containing metal. Furthermore, the contact resistances are not satisfactory in every case. Finally, the additional temperature treatment step is considered to be disadvantageous.

Furthermore, laser sintering methods for making contact with solar cells are known in the prior art. According to DE 10 2006 040 352 B3, a metallic powder is first of all applied to a substrate, the metallic powder is locally sintered or melted with the aid of a laser beam, and the metallic powder which has not been sintered or melted is finally removed.

One problem with this method is that the material which has not been sintered must be removed again and collected in a separate process step, which first of all means high use of material, and can then lead to losses. Furthermore, additional subsequent temperature treatment at 250 to 400° C. is required to ensure complete sintering, in order to achieve a good contact resistance.

### SUMMARY OF THE INVENTION

In view of this, it is a first object of the invention to disclose a method for making contact with a semiconductor substrate, which is particularly suitable for making contact with solar cells.

It is a second object of the invention to disclose a method for making contact with a semiconductor substrate, which allows a particularly good contact quality with little effort.

It is a third object of the invention to disclose a solar cell having a particularly good contact quality.

According to the invention, these and other objects are achieved by a method for making contact with a semiconductor substrate, in particular for making contact with solar cells, in which a metallic seed structure is generated on the surface through a passivating layer or a dielectric layer by means of a LIFT process, and the seed structure is then reinforced.

The object of the invention is achieved completely in this manner.

The LIFT process (Laser Induced Forward Transfer) is known in principle in the prior art (cf. U.S. Pat. No. 4,970,196). In this case, an optically transparent mount material with a thin layer of the material to be applied is placed in front of a substrate to be coated. The material to be applied is locally heated through the optically transparent mount material with the aid of a laser beam to such an extent that it is released from the mount material and is precipitated on the immediately adjacent substrate. At relatively high laser intensities, particularly when using a pulsed laser, the material is heated to such an extent that it reaches the vaporization point, and such that the transfer process to the substrate surface is assisted and driven by the metal vapour pressure.

According to the invention, this method is now used to transfer thin metal layers to a semiconductor substrate, in order to make contact with it. A contact which adheres well and has good conductivity is obtained by subsequent reinforcement of the seed structure produced by the LIFT process.

The use of the LIFT process makes it possible to produce high-quality contacts with very little effort. This results in considerably better contact resistances than in the case of screen-printing methods. The method is highly flexible, since no mask has to be used for structuring. Changes to the structure (line width, position of the lines, line height etc.) can be implemented more easily than in the case of imaging methods. All that is necessary for this purpose is to appropriately control the laser, for example with the aid of a scanner. In addition, a multiplicity of metals can be deposited with the aid of the LIFT process. Furthermore, very thin lines can be represented, thus resulting in little coverage of the solar cell surface eon the front face, which is advantageous for the efficiency of the solar cell. Finally, the aspect ratio (ratio of the height to the width) of the lines can be set within wide ranges. For example, the width of the lines can be reduced without having to reduce the conductivity of the lines.

According to a further refinement of the invention, the seed structure is reinforced by an electrochemical method or a non-electrical method.

Although, in principle, other methods are also feasible for reinforcement of the seed structure, the electrochemical method is a highly cost-effective method, by means of which layers of good conductivity can be produced in a cost-effective manner.

According to a further refinement of the invention, the seed structure is produced through a cover layer on the substrate surface.

According to the invention, the energy which is produced during the LIFT process can be used to produce the metallic seed structure directly through a cover layer which normally adheres to the substrate surface. In general, solar cells are provided on their front face with an antireflective layer, which has dielectric characteristics. Because the local energy during the LIFT process is sufficiently high, the seed structure can be “fired” directly at the substrate surface through the cover layer or antireflective layer.

This means that contact is made very cost-effectively and highly effectively without additional process steps. In a corresponding manner, the seed structure can be produced directly on the substrate surface through a passivation layer on the rear face of a solar cell.

It is self-evident that, in principle, the seed structure can also be produced directly on the substrate surface through a sequence of layers, provided that the laser energy is appropriately controlled.

According to a further refinement of the invention, a seed structure composed of a first metal is first of all produced by means of the LIFT process on the semiconductor substrate, and is then reinforced with a different metal.

For example, it is first of all possible to work with a seed structure which adheres well on the substrate surface, and has little diffusion. This layer can then be reinforced with a different metal, for example with silver or copper, which has a considerably higher conductivity. In this case, the first layer can act as a diffusion barrier. For example, this may be a nickel layer.

In addition, it is first of all possible to produce a first seed structure composed of a first metal by means of an LIFT process, and then to produce a further layer composed of a different metal, once again by means of an LIFT process.

Furthermore, the first seed structure can also first of all be reinforced with the same metal, before a layer of a different metal is applied. Once again, this can be done, for example, by an electrochemical process.

A pulsed laser is preferably used for the LIFT process.

In this case, it is found to be particularly advantageous to use a pulse duration of at least 40 nanoseconds.

This makes it possible to prevent particle scatter and this has an advantageous effect on the quality of the contact layer that is produced.

In this case, it has been found to be particularly advantageous to use a laser beam which is focussed in the longitudinal direction, preferably a laser beam with an elliptical focus.

Furthermore, according to a further refinement of the invention, the first seed structure is transferred from a film mount to the substrate surface in a roll-to-roll process by means of the LIFT process.

This results in particularly cost-effective production, which is suitable for large-scale manufacture. In the case of the roll-to-roll process, a lateral offset of the relevant film mount after each laser writing process makes it possible to achieve very good material utilization of the metal coating which is provided on the mount film.

It is self-evident that the features of the invention which have been mentioned above and those which are still to be explained in the following text can be used not only in the respectively stated combination but also in other combinations or on their own, without departing from the scope of the invention.

### BRIEF DESCRIPTION OF THE DRAWINGS

Further features and advantages of the invention will become evident from the following description of one preferred exemplary embodiment, with reference to the drawing, in which:

FIG. 1 shows the current/voltage characteristic of a solar cell after making a nickel contact on the front phase, which was produced by an LIFT process and was electrochemically reinforced;

FIG. 2 shows the dependency of the contact resistance from the movement speed of the laser beam for a nickel layer applied by means of an LIFT process;

FIGS. 3a), b), c) show the various phases during the application of a metal layer by means of an LIFT process, illustrated schematically and

FIGS. 4a), b) show schematic illustrations of electrochemical reinforcement of a previously produced seed structure, by means of an electrochemical method.

### DESCRIPTION OF PREFERRED EMBODIMENTS

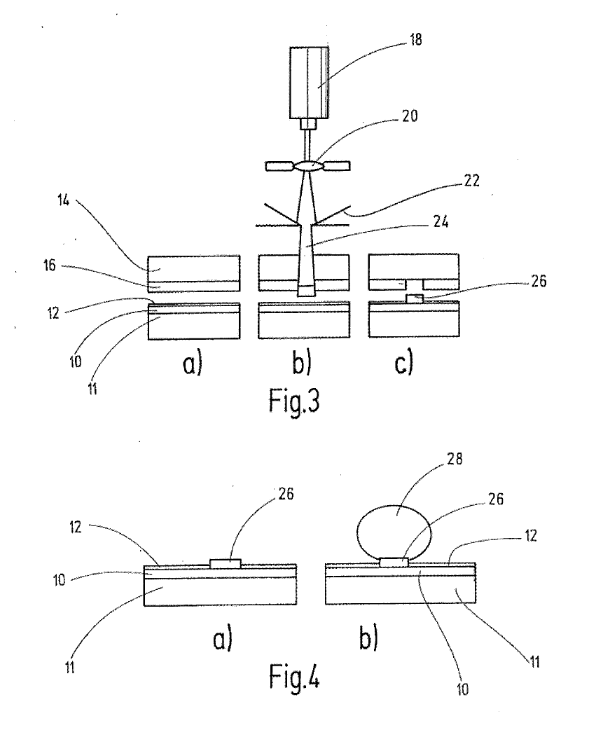

The principle of the LIFT process will be explained in more detail in the following text with reference to FIG. 3.

During the production of a solar cell, this solar cell must be provided with a metallic contact on the front face and on the rear face. By way of example, FIGS. 3a), b), c) show a p-type-doped base material (Si wafer or polycrystalline Si) which is annotated 11, on the front face of which a layer of n-type-doped material is located, which forms the emitter. This substrate layer 10 is provided with a cover layer 12, which is an antireflective layer, such as a silicon-nitride layer with a layer thickness of 50 to 100 nm.

A metallic seed structure 26 is now produced directly on the surface of the substrate layer 10, through the cover layer 12, by means of the LIFT process. For this purpose, a mount material 14 in the form of a thin glass layer or a thin film is arranged in the immediate vicinity in front of the substrate layer 10, and is provided with a thin metal layer 16 on its side facing the substrate layer 10. By way of example, this may be a nickel layer.

FIG. 3b) now shows how a portion of the thin metal layer 16 is detached locally from said thin metal layer 16 with the aid of a laser beam 24 and, as shown in FIG. 3c), is fired directly onto the surface of the substrate layer 10, through the cover layer 12. This is done using a pulsed laser 18, which directs a laser beam 24 through the transparent mount layer 14 onto the metal layer 16 through a lens 20 and a gap 22. The high energy of the pulsed laser beam locally detaches the metal layer 16 and vaporises it through the cover layer 12, in order to be precipitated as the seed structure 26 on the surface of the substrate layer 10, as in FIG. 3c). This layer is referred to here as a “seed structure” since it is in general reinforced by an additional method step, for example an electrochemical step.

It is self-evident that the illustration in FIG. 3 is only purely schematic and does not reflect the actual size relationships. In addition, it is self-evident that the LIFT process can also be used to produce the seed structure 26 through a plurality of layers, provided that the energy is controlled in a suitable manner.

The LIFT process is preferably carried out using a pulsed laser which is operated with a pulse duration of approximately 40 nanoseconds. By way of example, this may be an Nd:YAG laser with a wavelength of 532 or 1064 nm. In principle, the LIFT process is largely independent of the wavelength. However, a specific wavelength may also be preferred, depending on the metal to be transferred and the respective absorption.

The seed structure produced as shown in FIGS. 3a), b) and c) is then reinforced as shown in FIG. 4, as indicated schematically in FIG. 4b). By way of example, an electrochemical method or a non-electrical method can be used for this purpose. This results in a reinforcing structure 28 with a high conductivity. This may be composed of the same material as or of a different material from the seed structure 26.

The use of the LIFT process allows very wide freedom for configuration during the application of the contact structures. By way of example, the laser beam can be controlled in a suitable manner by a scanner, in order to produce a desired seed structure on a substrate surface 10.

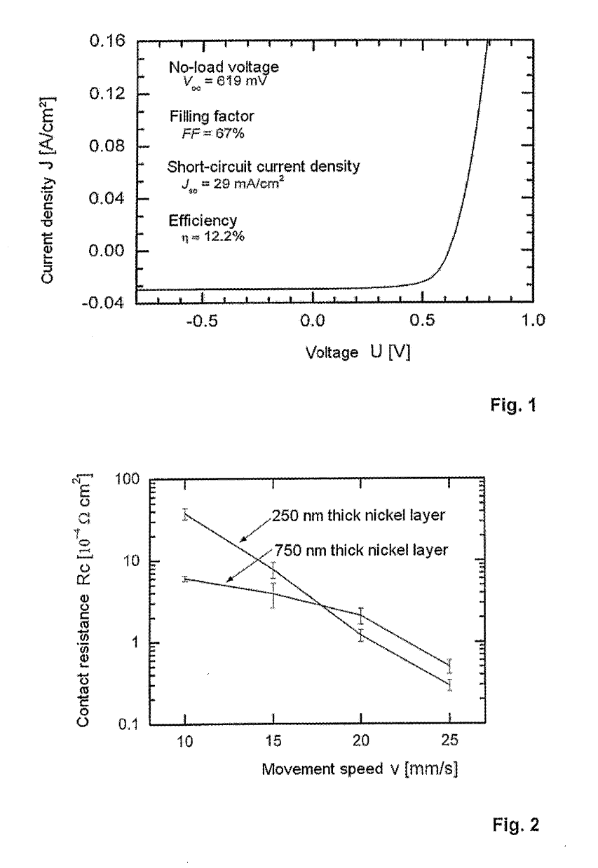

FIG. 1 shows a current/voltage characteristic of a solar cell with a nickel contact on the front face, which was produced by means of an LIFT process. The seed structure was applied directly through the antireflective coating on the wafer (n-doped Si emitter), and was then electrochemically reinforced. The characteristic shows that the contact produced in this way on the front face of the solar cell leads to a high-quality solar cell.

FIG. 2 illustrates the dependency of the contact resistance on the movement speed. A higher movement speed results in lower contact resistances. The best contact resistance achieved is 3×10⁻⁵ Ohm cm² on an emitter with a surface resistance of 55 Ohm per square with a nickel layer thickness of 250 nm on glass.

The LIFT process can also advantageously be used for making contact with a solar cell on the rear face.

A small contact area in comparison to the rest of the area is likewise desirable for making contact on the rear face. The remaining area is protected by a passivation layer, thus resulting in a more efficient solar cell.

Ag, Ti or Ni is preferably used to make contact with n-type material. In contrast, a different metal, for example aluminium is preferably used to make contact with p-type material. The respective materials may be selected depending on the respective layer with which contact is to be made, and may be applied in the LIFT process. The same or different materials may be used in the subsequent reinforcing step. For example, a nickel layer can first of all be applied as a diffusion barrier layer using the LIFT process, which is then first of all electrochemically reinforced, and to which a copper layer is then likewise applied, electrochemically.

The laser used has an elliptical focus with a width of approximately 5 μm and a length of approximately 20 to 30 μm.

What is claimed is:

1. A method of contacting a solar cell on a surface thereof which is covered by an outer cover layer which is selected form the group consisting of a passivating layer and a dielectric antireflective layer, comprising the steps of:
generating a first metallic seed structure through said outer cover layer using a first metal in a first laser induced forward transfer LIFT step;
in a second laser induced forward transfer LIFT step generating a second metallic seed structure on said first metallic seed structure using a second metal different from said first metal; and
reinforcing said seed structure thereafter.

2. The method according to claim 1, wherein said seed structure is reinforced by an electrochemical method.

3. The method according to claim 1, wherein said seed structure is reinforced by a non-electrical method.

4. The method according to claim 3, wherein the seed structure is generated through an antireflective layer on a front face of said solar cell.

5. The method according to claim 3, wherein the seed structure is generated through a passivation layer on the rear face of a solar cell.

6. The method according claim 1, in which a seed structure composed of a first metal is first of all generated by means of the LIFT process on the semiconductor substrate, and is then reinforced with a different metal.

7. A method of contacting a solar cell on a surface thereof which is covered by an outer cover layer which is selected form the group consisting of a passivating layer and a dielectric antireflective layer, comprising the steps of:
generating a metallic seed structure through said outer cover layer using a first metal in a first laser induced forward transfer LIFT step; and
reinforcing said seed structure with said first metal thereafter.

8. The method of claim 7, in which said seed structure is configured as a diffusion barrier layer.

9. The method of claim 8, in which the seed structure is generated from a metal selected form the group consisting of nickel and a nickel alloy.

10. The method of claims 7, wherein after reinforcing said seed structure with said first metal, a layer of a different metal is applied.

11. The method of claim 1, wherein a pulsed laser is used during the LIFT process.

12. The method of claim 7, wherein a pulsed laser is used during the LIFT process.

13. The method of claim 11, in which a laser with a pulse duration of at least 40 nanoseconds is used.

14. The method of claim 12, in which a laser with a pulse duration of at least 40 nanoseconds is used.

15. The method of claim 1, in which a laser beam which is focussed in the longitudinal direction is used for the LIFT process.

16. The method of claim 7, in which a laser beam which is focussed in the longitudinal direction is used for the LIFT process.

17. The method of claim 1, in which the first seed structure is transferred from a film mount to the substrate surface in a roll-to-roll process by means of the LIFT process.

18. The method of claim 7, in which the first seed structure is transferred from a film mount to the substrate surface in a roll-to-roll process by means of the LIFT process.

19. A method for contacting a semiconductor substrate on a surface thereof which is covered by an outer cover layer which is selected form the group consisting of a passivating layer and a dielectric layer, comprising the steps of:
generating a metallic seed structure through said outer layer using a laser induced forward transfer LIFT step; and
reinforcing said seed structure thereafter.

20. A solar cell having at least one contact having a metallic seed structure which is generated using a laser induced forward transfer LIFT process extending through a dielectric or passivating layer and having an reinforcing layer on top of said seed structure.
